(19) United States
(12) Patent Application Publication
(10) Pub. No.: US 2024/0298426 A1
(43) Pub. Date: Sep. 5, 2024

(54) Device for Dissipating Heat From Electronic Components in an Electronics Housing

(71) Applicant: Siemens Aktiengesellschaft, München (DE)

(72) Inventors: Florian Eder, Erlangen (DE); Sven Böhler, Heidelberg/Weststadt (DE); Sven Pihale, Stopfenheim, Bayern (DE)

(73) Assignee: Siemens Aktiengesellschaft, München (DE)

(21) Appl. No.: 18/574,978

(22) PCT Filed: Jun. 20, 2022
(86) PCT No.: PCT/EP2022/066703

§ 371 Date: Dec. 28, 2023

(30) Foreign Application Priority Data
Jun. 29, 2021 (EP) 21182506.2

(51) Int. Cl. H05K 7/20

(52) U.S. Cl. CPC H05K 7/20336; H05K 7/20327

(57) ABSTRACT

Various embodiments of the teachings herein include a device for dissipation of heat from electronic components disposed in an electronics housing. An example device includes a condensate transport to channel a working fluid from a cold site in the electronics housing to the electrical, optoelectrical and/or electronic components, removing waste heat from the components via enthalpy of evaporation of the working medium. The condensate transport includes a surface comprising adhesive and/or varnish with fibers directed thereon.

### CROSS-REFERENCE TO RELATED APPLICATIONS

This application is a U.S. National Stage Application of International Application No. PCT/EP2022/066703 filed Jun. 20, 2022, which designates the United States of America, and claims priority to EP Application No. 21182506.2 filed Jun. 29, 2021, the contents of which are hereby incorporated by reference in their entirety.

### TECHNICAL FIELD

The present disclosure relates to electronics. Various embodiments include methods and/or devices for dissipation of heat from electronic components disposed in an electronics housing.

### BACKGROUND

Electronics as a key technology provides electronic components in miniaturized form on a chip, especially integrated circuits, “ICs”. These may comprise circuits having several billion electronic components—especially diodes and/or transistors, such that even highly complex circuits such as microprocessors and memory chips can be accommodated in semiconductor platelets of a few square millimeters in size. The rectangular semiconductor platelets are called chips. It is increasingly the case that whole systems such as processors, interface circuits, and memory elements can be implemented on a single chip. These are produced in ultraclean rooms and are very sensitive. For use, the chip is installed into a housing.

These are primarily not electronic components where there are chips with many transistors (control electronics) because these are likely to have comparatively low waste heat densities, but mainly electronic components that have few transistors by comparison or even only individual transistors (power electronics) but produce large amounts of waste heat.

Most chips are packaged, meaning that the chips are mounted on a substrate, the electrical contact connection of the substrate to the chip is performed (for example via wire bonding processes), and then the whole structure is packaged once again, for example encapsulated with a molding compound. This construction is often also referred to as a chip. This concerns power electronics, i.e. electronics having high waste heat densities which originate from electrical losses from the switching of high electrical currents.

These circuits are usually not very complex in electrical terms. It is often the case that large individual transistors in a planar design—e.g., the chip, which is neither encapsulated nor electrically contact-connected—are usually arranged one alongside another on a substrate in a relatively large number. The electrical contact connection is usually effected via wire bonding, but soldering and/or sintering are also used. Since very high currents and powers are being switched in these circuits, each contact is usually bonded to multiple wires in order to increase current capacity.

Constant miniaturization with simultaneously increasing power is requiring ever more efficient dissipation of heat in these electronic components. This is placing high demands on the housing. For example, for the progressive vertical integration of the individual components in electronics, the performance of the cooling concepts known to date is inadequate. This is especially true because many cooling concepts still rely on the use of thermal paste for thermal binding of the heat sources to the cooler. For example, a layer of thermal paste often constitutes a risk to sustained reliability, but the alternative—a larger cooling body—is a barrier to the required miniaturization.

Dissipation of heat in modern power electronics has to date been achieved by transferring the waste heat from the electronic components that has been absorbed primarily by a thermal paste to ceramic printed circuit boards, for example backside metallization, for example direct copper bonding, “DCB”. This backside metallization is a consequence of the fact that the chips are mounted on a substrate, with electrical wiring via wire bonding on the side facing away from the substrate. This side with the wiring is difficult to utilize for binding to cooling means in geometric terms; therefore, the waste heat is generally removed via the substrate plate.

For example, such a heat removal chain takes the following form: power chip->assembly material on the substrate, for example solder, thermally conductive varnish and/or adhesive->substrate->thermal paste, e.g. oil, wax and/or with or without ceramic fillers/metal filler, and finally->cooling body. One example of a thermally conductive substrate plate that provides electrical insulation is an aluminum oxide ceramic. This still has double-sided metallization. The chip-side metallization is processed by standard structuring methods so as to form conductor tracks and bonding pads; the cooling side metallization is used, for example, for soldering and/or sintering attachment of cooling bodies, which is costly and time-consuming; this is another reason why thermal pastes are popular.

Thus, after the insertion of the chip, or of the printed circuit board and/or the direct copper bonding (DCB), into an electronics housing, for example into a plastics housing, the reverse side of the DCB is encapsulated. The ceramic, which, as the shield—together with the metallization—is responsible for the dissipation of waste heat from the power elements, conducts the waste heat onward into a base plate made of metal, which is in turn attached again to an active cooler, for example via ventilators and/or water cooling.

U.S. Pat. No. 4,047,198 from 1977 discloses a housing for a microelectronic device which is integrated in a vacuum-tight manner into a housing, wherein the housing is coated fully and uniformly on the insides with a dielectric powder, in such a way that a dielectric coolant is passed onward within the housing after evaporation.

### SUMMARY

The teachings of the present disclosure include a cooling concept for miniaturized electronic components that efficiently cools high-performance and/or miniaturized components, wherein controlled chip cooling comprising a fluid transport layer which in turn reflects a complex surface topography is to be provided. The challenge here is to transfer heat from a system which is electrically insulating to a cooled site in the housing at which there is then an interface, for example, with coolants, for example cooling fins, ventilators and/or water.

Thus, various embodiments of the teachings herein include devices for dissipation of heat that permits the creation of a surface, for example what is called conformal coating for the inside coating of housings, which is capable of conducting a coolant, and which is in particular also producible in standard manufacturing processes for electronics manufacture. Some include a surface which, as well as good fluid transport properties, also ensures very low hindrance of the release of heat and/or vapor in power electronics. This is not the case, for example, in the prior art, U.S. Pat. No. 4,047,198.

For example, some embodiments of the teachings herein include a device for dissipation of heat from electronic components (3) disposed in an electronics housing (1), which dissipates waste heat via the enthalpy of evaporation of a working medium, wherein means (7, 8) of transporting a condensate of the working medium (9) from a cold site in the electronics housing to the electrical, optoelectrical and/or electronic components (3) that produce waste heat are comprised, and these means (7, 8) of transporting the condensate are implemented at least partly by a surface comprising adhesive and/or varnish with fibers directed thereon, in the form, for example, of a “flocked carpet”.

In some embodiments, the electronic components (3) are arranged on a printed circuit board (2) in the electronics housing (1).

In some embodiments, the printed circuit board (2) is part of the electronics housing (1).

In some embodiments, the wall of the electronics housing is at least partly metallic.

In some embodiments, the wall of the electronics housing is at least partly made of fiber composite material and/or of composite material.

In some embodiments, the working medium is a coolant having a boiling point within the working range of electronics, i.e. 10° C. to 200° C.

In some embodiments, the working medium is a nonflammable or low-flammability coolant having a GWP value of less than 170.

In some embodiments, the working medium is a fluid having a boiling point at standard pressure of 10° C. to 200° C.

In some embodiments, a flocked carpet with or without structuring is provided over part or all of the inside of the housing.

In some embodiments, a coating with an adhesive and/or varnish layer is provided over part or all of the inside of the housing.

In some embodiments, the flocked carpet is provided throughout or in the form of patterns and/or free areas.

In some embodiments, the electronic components (3) disposed in the electronics housing (1) have been coated with a protective varnish coating which, in the uncured state, acts as adhesive for the flocking.

In some embodiments, means of transporting the condensate (7) also comprise open pores in ceramics, foams and/or composite materials.

In some embodiments, means of transporting the condensate (7, 8) comprise channels.

In some embodiments, the printed circuit board (2) is part of the electronics housing (1).

### BRIEF DESCRIPTION OF THE DRAWINGS

The teachings of the present disclosure are elucidated in detail hereinafter with reference to the figures. In the figures:

FIG. 1 shows an example of a prior art electronics housing 1 with a printed circuit board constituting a heat source embedded into a thermal paste; and

FIG. 2 shows a diagram of an example device incorporating teachings of the present disclosure.

### DETAILED DESCRIPTION

As an example, some embodiments of the teachings herein include a device for dissipation of heat from electronic components disposed in an electronics housing, which dissipates waste heat via the enthalpy of evaporation of a working medium, comprising a transport for condensate of the working medium from a cold site in the electronics housing to the electrical, optoelectrical and/or electronic components that produce waste heat, and the means of transporting the condensate are implemented at least partly by a surface comprising adhesive and/or varnish with fibers directed thereon, in the form, for example, of a “flocked carpet”.

“Means of transporting the condensate” refer here, for example, to the fibers that absorb the condensate via capillary forces and, according to the vapor pressure gradient, return it to the site in the housing that is the hottest and where the most working medium evaporates again.

“Flocked carpet” refers to any point in the interior of the housing where there are fibers aligned on a varnish and/or adhesive surface. The flocked carpet within a housing may be the same or different and cover the full area or be structured, i.e. be present partially and/or in regions.

This technique enables fluid transport pathway structures having tailored properties (fiber material, fiber length and/or fiber cross section, or fiber thickness and/or fiber density). In particular, it is also possible to balance out any layer properties (thermal resistance) at surfaces that produce waste heat by structuring the flocked carpet, since it is possible to adjust in a controlled manner where exactly on the chip and around the chip the flocked carpet is disposed and in what way—with regard to adhesive material, adhesive thickness, fiber material, fiber length and/or fiber cross section, or fiber thickness and/or fiber density.

For example, in the middle of the chip, it would be possible to deliberately omit to apply the flocked carpet in order to enable unhindered evaporation of the working medium. According to the prior art, which envisages uniform coating of the insides, there is generally an excessively thick fluid layer above the chip, such that the dissipation of heat can take place only via the fluid. As a result, e.g. according to U.S. Pat. No. 4,047,198, the exit of vapor is hindered in an unfavorable manner at a site with high incidence of heat. But power densities in 1977 were of course not comparable with those of today.

In any case, the arrangement of the fibers at right angles to the chip surface provides a clear pathway, or one covered by adhesive at most, for evaporation of the working medium in all surface regions of the chip that are not covered by the fiber cross section, the surfaces of the chip that are either not coated at all or are covered only by adhesive varnish, which may even be more than 90% of the free chip surface area. It should be remembered here that the chip surface covered with adhesive which is not flocked with fibers is minimized in order that the adhesive layer—no matter how thin it may be—does not unnecessarily retain the waste heat in the chip.

In some embodiments, the materials of the directed fibers and the polarity of the working medium are matched to one another. For example, fibers used are polymer fibers, natural fibers, textile fibers and/or glass fibers, in particular, for example, fibers of polymers and/or copolymers, for example polyketone, polyether, polyester, polyamide, and/or polyimide fibers, alone or in any desired combinations.

If the surfaces of the fibers are treated, and optionally also the inner surfaces in the case of hollow fibers, for example by wet-chemical treatment, by corona treatment and/or by plasma treatment, for example low-pressure plasma treatment, these become polar at least in some regions. Thus, the sorption properties of the fiber surfaces can be matched to the respective working medium.

It is possible to influence both the rise height and the volume flow of the fibers by surface treatment, especially also with regard to the performance thereof in the saturated state.

In some embodiments, the fiber surface is matched to the working medium by treatment and/or coating thereof.

In some embodiments, further advantageous optimizations are achieved within the device by mixing differently treated and/or untreated fibers and optionally solvent mixtures of the working medium.

Semiconductor chips of integrated circuits, and diodes, transistors, for sealing against environmental influences, for further processing, for electrical connection and for dissipation of heat, need housings, called the electronics housing. There are wired components thereof for through-hole technology, “THT”, and electronics housings for surface-mounted technology, “SMT”, or surface-mounted devices, “SMD”. These electronics housings that are known per se can be converted to a vapor chamber by simple measures, such as coating, especially flocking, of the inner surfaces, e.g. the inside of the housing of the chip surface, the printed circuit board surface, including the backsides of each, and corresponding sealing, which provides highly efficient cooling for the miniaturized components of the chip that are present in the vapor chamber.

In some embodiments, there is flocking of the full area or of regions. Flocking refers to the “bombardment” of a substrate previously provided with adhesive and/or varnish with fibers, preferably with short fibers, especially preferably short-staple, textile, synthetic and/or glass fibers, which are fixed after the bombardment by curing of the adhesive. For example, monofil fibers are also suitable, for example including textile monofil and/or ceramic fibers.

In particular, in the case of flocking by electrostatic charging, it is possible to achieve complete alignment of the fibers on the substrate, especially alignment at right angles to the substrate, because the charged fibers line up along the electrical field lines. Especially in order to maintain the evaporation areas within the housing and in particular also on the surfaces and reverse sides of the waste heat-producing electronic components, alignment at right angles to the substrate is very important under some circumstances.

In some embodiments, not all inner surfaces of the housing and all outer surfaces of the waste heat-producing electronic component are flocked, but only as required. The requirement can also be calculated by simulation but can alternatively or additionally be determined by empirical means. For example—especially on the waste heat-producing electronic component—flocking in regions is suitable, for example distributed in a regular manner, in the form of a pattern and/or else irregularly and/or even randomly.

By simulation and measurement, it is possible to create a kind of “waste heat map” in advance, which shows the hotspots in the populated electronics housing in operation with the electronic component. Accordingly, the flocking can be varied and adjusted in every respect—density, cross section, material, coating and/or length of the fibers arranged, and adhesive material and/or layer density and/or layer thickness.

In some embodiments, the pattern, the area, whether the fibers are actually arranged regularly or irregularly, etc. may be aligned and matched to the local conditions in the electronics housing. In the case of flocking with fibers—which are ultimately vertical on the substrate—in some embodiments, the electrostatics and the fiber flight in particular are optimized in advance by simulations during the bombardment such that the majority, and at least a proportion of greater than 50% by weight of the fibers, does indeed land vertically on the substrate surface. In some embodiments, a proportion of greater than 75% by weight or of greater than 95% by weight of the fibers is in a vertical arrangement, based on the total mass of the fibers present on the flocked carpet.

What is meant by vertically arranged here is fibers arranged at right angles, e.g. in the range from 70° to 110°, or in the range from 85° to 95°. For example, numerical flow simulations or computational fluid dynamics (“CFD”) simulations are suitable for the purpose. In particular, for example, the balance of evaporation when specific surfaces free of fiber flocking are obtained is also apparent by simulation. This relates in particular to the surface of the waste heat-producing electronic component(s) within the housing, in relation to the question of whether and, if so, where flocking improves the overall balance of cooling.

In some embodiments, the flocked carpet is in structured form. This means that the flocked carpet has voids. For example, the flocked carpet is present in specific patterns and/or randomly distributed covered and uncovered, flocked and unflocked regions. What is meant here by “covered” is that adhesive and/or varnish is present on the surface. Flocked regions can only exist in covered regions, and a “flocked region” refers to the regions having fibers aligned on the adhesive and/or varnish.

Other regions of the waste heat-producing electronic component for dissipation of heat can simply remain untreated. For example, the flocked carpet may be provided in the form of stripes, with constant alternation of a stripe of flocked carpet and a stripe of untreated chip surface. As well as alternating stripes, it is also possible for there to be any other patterns of the “flocked carpet” comprising regular and/or static elements.

By means of simulations, by empirical means and/or via considerations, it is also possible to optimize the manner of flocking of the insides and/or the outsides of the waste heat-producing electronic component within the housing. The manner of flocking may for the first time vary with regard to the type of fiber, i.e. in terms of material. It is possible to use uniform fibers or fiber mixtures in the flocking. The fibers may have different lengths, different diameters and/or different densities. They may likewise be present in different concentrations, i.e. number of fibers per unit area in the flocked carpet.

The fibers are chosen with regard to optimization of their capillary forces in interaction with the working medium, i.e. a coolant for example. It should be remembered here that the transport volume, the rise height, the sorption height and/or the flow rate of the working medium can be influenced via the matching of the microstructure and/or fiber surface area to the evaporation at the respective site in the housing and/or by virtue of the optimization of the wetting properties of the fibers by the working medium. All these influences can be optimized toward a maximum either empirically and/or with support by simulations.

In some embodiments, so the capillary forces can act optimally, the fibers are wholly or partly surface treated before the flocking such that the fiber surface shows the highest possible sorption values, best possible attraction and/or binding of the coolant molecules at the surface of the fibers with regard to the coolant to be transported. The surface treatment of the fibers can be effected, for example, in a wet-chemical treatment, in a plasma, as a coating operation with an organosilicon layer and/or slip, or else by processing with alcohol(s), water and/or any combinations of the aforementioned surface treatments.

For instance, within the housing, flocking is possible on different inside faces with different intensity, fiber density, or type of fiber. Adhesives used may, for example, be the following materials: all standard adhesives and adhesive mixtures, and compounds used as printed circuit board protective varnish and/or compound classes such as epoxide, acrylate etc.

In some embodiments, the adhesive and/or varnish cures via thermal curing. In some embodiments, a thin adhesive and/or varnish application may be less than 15 μm, less than 10 μm, less than 5 μm, and/or less than 2 μm.

In some embodiments, the adhesive and/or varnish on which the fibers “stand” may be at least partly thermally conductive. This can be effected, for example, via filling of the adhesive and/or varnish with thermally conductive particles. A standard printed circuit board protective varnish formulation may—in modified or unmodified form—be used here as “adhesive”, provided that the flocking precedes the curing of the varnish.

In some embodiments, flocking is not present everywhere, and so regions in which evaporation of the working fluid is to take place in particular remain unflocked by leaving them clear. Furthermore, even in the adhesive-coated regions where a flocked carpet is present, it is not the case that the complete surface is covered by the fiber cross section. These regions of the inner surface and/or of the chip surface that may be covered by adhesive but not by fiber cross section may thus account for well above 50%, especially well above 75%, and/or well above 90% of the coverable surface area in the housing.

“Housing” or “electronics housing” refers in the present context to a housing composed of plastic, ceramic, composite material and/or metal, or metal alloy. The electronics housing may comprise any desired combinations of the above-detailed materials; it serves firstly as casing and/or carrier for the electrical, optoelectrical and/or electronic components, especially for printed circuit boards, switches, contacts, bushings, and optionally also operating elements, and on the other hand serves for electrical/electronic protection of the components from environmental stresses, and it finally serves to protect the user from electrical, electronic and/or optoelectrical components. When an electronics housing is used as vapor chamber, the airtightness of the electronics housing may be designed such that a reduced pressure can be maintained.

“Means of transporting the condensate” in the present context refer to a system produced by partial or full-area flocking with fibers, surface, coating, porous material within the housing, which, in association with the evaporation of the working fluid by the waste heat from the electronic component(s), at a cold site distant from the component within the electronics housing, takes up the condensate, transports it and steers it back to the component. The “means of transporting the condensate” comprises structures there that are correspondingly warmed up by the waste heat from the component and enable evaporation. In order that the evaporation can proceed on the component(s) even in spite of flocking with fibers, in an advantageous embodiment, for example only to a partial extent, especially also in stripe form, for example, in a pattern, for example in checked or rhomboid form, longitudinal stripes with randomly distributed bridges, etc., the surface of the component(s) is alternately flocked and unflocked region by region. But the flocked regions of the surface may also be flocked with different density, or flocked with fibers of different thickness.

Supplementary examples of the means of transporting the condensate, as well as the fibers present in the flocked carpet, are also further coatings having channels, pores, open pores, fibers, hollow fibers, fiber scrims, layers, foams, varnish layers, porous structures, such as mats. The surfaces of the means are preferably more dielectric than electrically conductive, where polarity of the surface is preferably matched to the working fluid, for example such that it absorbs the condensate.

These additional means of transporting the condensate are applied, for example, as a spray-applied coating, painted coating, in the form of a structure produced on a metallic surface, for example with polarization of the surface suitable for absorption of the condensate. Suitable surface polarization can be effected via a measurement of wetting and/or a measurement of contact angle.

In some embodiments, the working medium used is a fluid such as an organic solvent. A suitable working medium, also referred to hereinafter as “working fluid” or merely as “fluid”, is selected according to various aspects. For example, it is essential that the working medium is of low flammability. An additional factor is that the working fluid has a boiling point within the temperature range of the working temperature of electrical, electronic and/or optoelectrical components.

The working medium must not be corrosive, and it needs to have an appropriate boiling point in order that it evaporates by virtue of the waste heat from the components under the conditions of the vapor chamber, in particular at a reduced pressure of 0.5 bar or less, and on the other hand condenses again at a cold site within the same vapor chamber.

In some embodiments, the working fluid is dielectric or electrically insulating in order that it insulates the individual components within the electronics housing from one another. In some embodiments, the working fluid has a dielectric constant, higher than air, which has a standardized dielectric constant of 1.

The use of fluoro ethers as working medium has a few major advantages with regard to electrical insulation, flammability etc. At the same time, however, these substances are not so popular because their enthalpy of evaporation is only 1/10 that of water. The chemical nature of these fluoro ethers and/or perfluoro ethers—depending on the completeness of the substitution of the hydrogen atoms on the ether by fluorine atoms—is that they exert virtually no physical interactions, for example have very low surface energies, either with a substrate to be wetted or with themselves—for example have low inclination to form a spherical shape. These properties are advantageous in the working medium with regard to the general wetting of surfaces and hence also the filling of a transport layer. At the same time, however, such liquids of relatively low polarity also have disadvantages with regard, for example, to the overcoming of heights by sorption/capillary force.

In some embodiments, the working medium used may therefore be either polar or nonpolar fluids, for example the nonpolar fluoro ethers, and/or else polar fluids, such as alcohol, ether, water, organic solvents and/or any desired mixtures. The use of fluorinated liquids has been found to be especially advantageous, especially those comprising fluoro ethers, for example monosubstituted, disubstituted or more highly fluorine-substituted ethers, have been found to be advantageous in tests because they are suitable owing to their generally high dielectric constants for increasing the voltage gaps between the electrical, electronic and/or optoelectrical components within the electronics housing.

For example, fluoro ethers have been used successfully in the form of commercial 3M™ Novec™—especially 3M™ Novec™ 7200. On the other hand, it has been possible to successfully use the commercial antifreezes known by the “Galden HAT PFPE Heat Transfer Fluids”, especially “Galden HAT Low Boiling”, from Kurt J. Lesker Company.

The class of the fluoro ethers includes, for example, methyl nonafluoro-n-butyl ether, methyl nonafluoroisobutyl ether, ethyl nonafluoro-n-butyl ether, ethyl nonafluoroisobutyl ether and any mixtures of these fluoro ethers with one another and/or with other organic solvents.

The class of alcohols and also pure distilled water are also suitable as working medium.

Because the surface tension of the liquid influences the sorption properties—or the capillary force—of the means of transporting the condensate, some embodiments include a means of transporting the condensate that has a suitable surface tension matched to the working medium. A heat pipe, just like a vapor chamber, each of which work by the same principle but merely have different shapes, are apparatuses for heat transfer that permit a high heat flow density with utilization of enthalpy of evaporation of a working medium. In this way, it is possible to transport large amounts of heat in a small cross-sectional area. The ability to transport energy in the case of a heat pipe depends to a crucial degree on the specific enthalpy of evaporation of the working medium.

Factors of lesser importance are both the thermal conductivity of the working medium and the thermal conductivity of the electronics housing wall. For reasons of efficiency, a vapor chamber is usually operated only slightly above the boiling temperature of the working medium at the warm site, for example above or below the chip, and only slightly below the boiling temperature of the working medium at the cold site, for example at maximum distance from the heat source.

A heat pipe and/or vapor chamber exploit the enthalpy of evaporation and the enthalpy of condensation of a working medium in order to move high heat flows. The shell of the vapor chamber is frequently manufactured from copper, brass, bronze and/or aluminum or corresponding alloys. In some embodiments, the working medium in the interior is a coolant, for example ammonia, low-flammability organic solvent, e.g. cycloaromatic organic solvents, fluoro ethers, aprotic solvents, halohydrocarbons, for example 1,1,1,2-tetrafluoroethane, carbon dioxide, water, hydrocarbons, alcohols, and any desired mixtures. In some embodiments, the working medium used includes fluids having a boiling point between 10° C. and 200° C., between 40° C. and 160° C., and/or between 50° C. and 140° C.

The coolants and/or antifreezes used as working fluid, in the classification of coolants, may be classified as nonflammable (A1) and/or of low flammability (A2L). For example, the classifications are conducted by the ASHRAE classification. What is called a GWP value is fixed here, which, in the case of the working fluids usable here, is at a value below 170, below 150, and/or below 100. This already evaporates—for example also because of a reduced pressure in the electronics housing—at very low temperatures in the vapor chamber. If the vapor chamber takes on a higher temperature as a result of the heat source, the pressure will rise. If a lower temperature arises at the other end of the vapor chamber—for example as a result of external cooling, this causes the temperature to go below the dew point here and hence leads to condensation of the working medium. The pressure here will decrease. The pressure in the vapor chamber will flow, following the pressure gradient, to the colder site. The condensate will flow, driven by gravity, and will be returned to the site of evaporation by the capillary forces in the vapor chamber.

Because of the gaseous and liquid phases of the working medium within the vapor chamber, a supersaturated vapor is formed. By virtue of the small pressure differences in the vapor chamber, the temperature differences and hence the temperature differential which is established between the condenser and evaporator are also only small. A vapor chamber therefore has very low heat resistance. Since heat transfer takes place indirectly via the mass-based transport of latent heat—heat of evaporation or condensation, the use range of a vapor chamber is limited to the range between the melting temperature and the temperature of the critical point of the working medium. For the range from −70 to 60° C., it is possible to use ammonia, for example, as working medium. The porous structures for the reverse transport of the working medium even counter to gravity can be achieved by means of inserted copper wire braids (mesh), by means of grooves and/or by means of sintered copper particles on the inner face of the vapor chamber. The finer that structure is, the greater the capillary force.

The form of a vapor chamber in particular is even better suited to chip cooling than a heat pipe because the heat in a vapor chamber, rather than being transported away via a pipe, is distributed rapidly over a large area. In this way, the effects of significant hotspots as occur on the chip are minimized. For the vapor chamber, it is not necessarily the case that a porous inner wall is required for reverse transport of the condensed working medium to the site of the hotspot because this simply works via gravity, for example, when the hotspots are at the bottom in the vapor chamber and the vapor rises up to the cooler roof, where it condenses and falls back down again as droplets.

In some embodiments, an electronics housing is produced completely as a vapor chamber. In some embodiments, the vapor chamber electronics housing is prefabricated independently of the chip manufacture. The chip may be mounted and contacted respectively onto the vapor chamber electronics housing.

In some embodiments, only a portion of the electronics housing is executed as a vapor chamber.

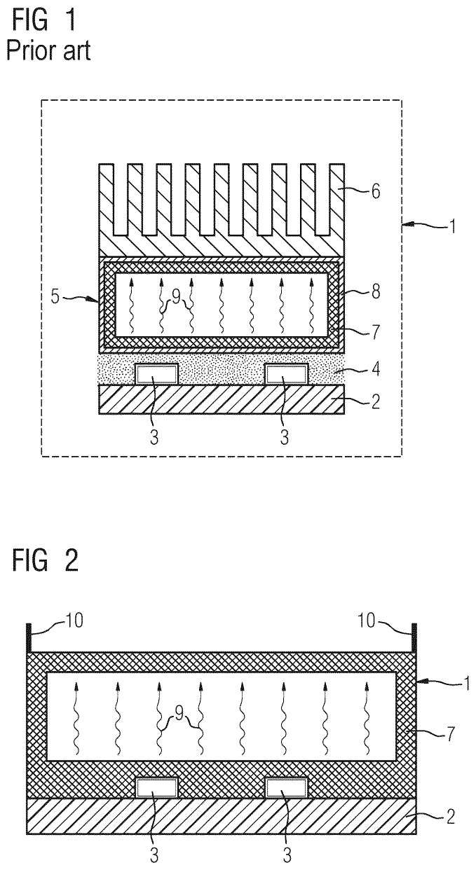

FIG. 1 shows an example from the prior art: an electronics housing 1 in which printed circuit board 2, chip, or components 3 constitute the heat sources 3, and are embedded into a thermal paste 4. A thermal paste 4 may contain, for example, a silicone oil and/or polyethylene glycol and serves to transfer heat between two objects, i.e., for example, the cooling surface and/or the electronics housing and a cooling body. The mounting faces of cooling bodies 6 and components 3 always contain unevenness of greater or lesser depth, which is balanced out by means of thermal pastes 4.

The thermal paste 4 adjoins a vapor chamber 5 with cooling bodies 6. In the vapor chamber 5, the porous structure at the inner faces 7 and a copper scrim 8 are apparent. In the vapor chamber 5, the working medium 9 evaporates from the warmer side downward to the cold site in the vapor chamber 5. The one or more cold sites in the vapor chamber 5 are the sites where the vapor chamber is actively cooled by means of a cooling unit, such as a cooling body 6 here. The working medium 9 thus evaporates in the direction of the cold site in the vapor chamber, where it cools down, condenses and flows back downward, driven by gravity and steered by means of transporting the condensate. The condensate 9 absorbs heat again there, evaporates and condenses again at the cold site. The bottleneck in the dissipation of heat from the components 3 according to the prior art shown here in FIG. 1 is the thermal paste 4, which transports heat away to the vapor chamber 5 only to an insufficient degree.

FIG. 2 shows an example device incorporating teachings of the present disclosure. As in FIG. 1, the electronics housing 1 is disposed flush with the printed circuit board 2. Atop the printed circuit board 2 and already within the vapor chamber 5 are the components and heat sources 3. According to the embodiment shown here, these are embedded into the porous structure 7 at the inner wall of the vapor chamber 5. The vapor chamber 5 still has contacts 10 at the top. Rather than the inefficient dissipation of heat via the thermal paste 4 and the vapor chamber 5 as required in the device of FIG. 1, the heat generated is released directly in the vapor chamber 5 in the region of the condensate 7 which flows downward along the porous structure of the “means of transport” in the example shown here, such that optimal cooling is possible.

As shown in FIG. 2, the electronics housing 1 becomes a vapor chamber 5 by virtue of a few additional steps. For this purpose, in a first step, a porous layer for liquid transport is applied. The exact configuration is addressed in detail below.

FIG. 2 shows an embodiment in which the printed circuit board 2 forms the base of the electronics housing 1. This is merely one of many possible arrangements of the printed circuit board within the electronics housing. For example, in some embodiments, the printed circuit board 2 is within the electronics housing or within the porous structure 7. In this embodiment, the working medium in the vapor chamber 5 flows around the printed circuit board 2 on either side.

In a second step, the electronics housing is filled with the working medium, reduced pressure is established, and the electronics housing is sealed. In the choice of working medium, it is possible to proceed in accordance with the selection in the case of conventional heat pipes. Useful materials for the electronics housing include metallic materials such as aluminum or copper. A further design of interest is the construction of the electronics housing from fiber composite materials; it would also be possible here to achieve the capillary effect by means of open fibers on the inner wall of the housing.

Since composite materials comprising two or more bonded materials based on fibers generally do not have isotropic heat conduction properties, appropriate preferential directions are established by controlled orientation of the fibers in order to achieve suitability as a structure within a vapor chamber, and these can then serve as means of transporting the condensate. The combination of vapor chamber 5 and electronics housing 1 thus not only dispenses with a component that has previously been bought in and reduces assembly work, but in particular gives rise to a high-performance cooling structure that additionally works in a maintenance-free and more failure-proof manner than the prior art, which works with thermal paste 4.

The use of the electronics housing 1 as vapor chamber 5 is possible in particular by means of a porous layer on the inside of the electronics housing for reverse transport of the liquid. This is applied to the inside of the housing and of the lid and to the printed circuit board and components, as shown in FIG. 2. The nature and configuration of this layer can influence the cooling output to a crucial degree, since the limiting capillary force and/or interaction limit frequently constitutes the crucial limitation on a vapor chamber. The following materials, by way of example but non-exhaustively, are useful for a porous coating of part or all of the inner surface of the electronics housing:
Zeolitic particles with organic binder
Open-pore plastic foams: the foams at the electronics housing wall can achieve additional mechanical protection,
Natural fiber weave,
Glass fiber weave, especially with adhesive bonding to the wall,
Powder coatings that are cured such that they remain in open-pore form, for example via spacers/template formers and/or blowing agents,
Aluminum oxide surfaces that are produced by appropriate etching processes on normal aluminum, for example what is called “flower-like alumina”, which refers to an aluminum having flower-like morphology via the AlO(OH) precursor through phase transformation.

In order to protect the components 3 from the working medium—for example for avoidance of electrical short circuits, corrosion or explosion, a “protective coating” may be applied atop the electronics, which does necessarily add significant heat resistance. Possible protective coatings if a working fluid is used that can cause one of the abovementioned problems—corrosion etc.—are, for example:
a protective coating comprising a thin film, producible for example by applying a thin film by lamination,
a protective coating comprising a plasma layer, and/or
a protective coating comprising a thermally conductive protective lacquer.

In some embodiments, an embodiment of the present invention can be produced as an “electronics housing-integrated vapor chamber” by the following schematic construction and assembly concept: The printed circuit board 2 is introduced into an electronics housing 1; A porous structure 7 is applied partly or wholly atop the printed circuit board 2 with the components 3 and on the insides of the electronics housing 1, then The air is pumped out of the electronics housing-integrated vapor chamber 5, and the working medium—which may of course also be a mixture of different working media—is introduced.

The result is a highly effective, sustainably stable high-end cooling solution for a chip in an electronics housing without costly materials, without bought-in parts and without major assembly work.

Rather than a separate module, the vapor chamber 5, which is applied to the surface of the electronics housing 1 to be cooled and contains the working medium, the working medium in the vapor chamber for cooling is present directly at the components, around the components and atop the printed circuit board 2, where the thermal paste 4 is present in previous devices. The transport step of conducting heat via the thermal paste 4 and the wall of the vapor chamber 5 is dispensed with, and hence the working medium has direct contact with the components 3, i.e. with the heat source.

The thermal resistance is thus reduced in the embodiments of the present disclosure compared to existing solutions. By virtue of the high diameter of the electronics housing by comparison with the vapor chambers obtainable to date, distinctly greater vapor and liquid flows are also possible, which enable the transport of higher flows of waste heat. By virtue of the cooling of the complete printed circuit board 2, no hotspots that damage the components 3 can arise. The heat is distributed by the immediate evaporation of the working medium 9 and transported to the condenser via the wet vapor area. The solution of the invention reduces the number of heat transitions to the absolute minimum necessary in technical terms and assures a maximum efficiency of heat flow, since the only materials used are those that constitute a compromise of suitability for use in principle for cooling applications and manufacturing-related processibility.

By virtue of the condensation of the coolant at the housing lid, improved removal of the heat is possible since a much greater surface area is available than in the case of the vapor chamber coolers installed to date. The construction to date also necessitated air cooling via a cooling body and cooling fins on the surface of the vapor chamber in order to be able to remove sufficient heat. By virtue of the greater surface area and direct connection to the frame construction made of metal, for example, it may be possible to efficiently remove the heat even without these additional elements. This enables even more compact designs and further miniaturization options.

Moreover, by virtue of coating of the printed circuit board on both sides with the porous layer and a corresponding installation in the housing, it is possible for the first time to achieve cooling on both sides of a printed circuit board. This could also be a decisive key enabler for new semiconductor generations with elevated switching and power densities since cooling on both sides constitutes a massive performance jump in heat removal technology.

By virtue of the selection and application of the porous layer, it is possible to influence the properties of the cooling system, for example the amount of working fluid pumped per unit time, in a controlled manner and to establish the required cooling performance.

In vapor chambers—“VCs”- and heat pipes—“HPs”—technically demanding material structures are used with regard to the geometric boundary conditions that exist. This concerns porous layers on the inside of thin metal tubes. Since HPs must generally not incur excessively high costs, the processes and methods that are used for production of the structures must be kept inexpensive and hence as simple as possible. The consequence is that the structures do fulfill their function in principle, but are in no way optimized. This relates not just to the pore volume, the porosity and the average pore diameter but also to the insulation of the reverse transport of the cooler media with respect to the warmer vapor phase.

By virtue of the absence of the geometric limitations, it is now possible to employ other materials and methods of generating porosity which, as well as distinctly simplified application conditions, locally better-resolved deposition of the porous layer and distinctly finer adjustment of the porosity properties, for example layer thickness, which is greatly limited in the HP and the VC, pore volumes, an average channel diameter, wettability->this ultimately influences the fluid conveying rate and the overall delivery volume.

Furthermore, the concepts described herein offers additional tuning options via the establishment of further surface properties, which can be achieved without difficulty via customary coating methods because of the geometric openness and accessibility of the concept. These are, for example, the controlled adjustment of the wettability of different surfaces. While evaporation surfaces should preferably have a hydrophilic configuration (this means improved wetting, avoidance of delayed boiling and hence again better heat transfer), condensation surfaces should have a hydrophobic configuration. This results in breakup of the condensate film and hence improved heat transfer at this interface by a factor of up to 10,000.

The transformation of the housing to a simultaneous VC cooling enables a high-performance cooling solution with low costs. The concept of a housing-integrated VC has the result that all regions are readily accessible (no narrow tubes). It is thus possible to use conventional methods (e.g., coating and assembly). This increases product quality and lowers costs. Since no thermal paste is required any longer, it is possible to further increase reliability.

Last but not least, advantages arise in applications where severe vibrations can occur. A conventional HP as cooling body should be regarded critically here, since the pseudo-bonded interfaces fail to some degree.

In the prior art, the heat to be removed from the electronic, optoelectrical and/or electrical component is first transferred to the thermal paste and then via the housing into the vapor chamber and thence into the working fluid. In the embodiments described herein, the heat to be removed is transferred directly from the chip into the working fluid.

The teachings for the first time describe a device for dissipation of heat from electronic components disposed in an electronics housing that does not rely exclusively on primary dissipation of heat via a thermal paste. Instead, the heat is dissipated via a working medium that provides cooling output in the electronics housing via evaporation and condensation.

What is claimed is:

1. A device for dissipation of heat from electronic components disposed in an electronics housing, the device comprising:
a condensate transport to channel a working fluid from a cold site in the electronics housing to the electrical, optoelectrical and/or electronic components, removing waste heat from the components via enthalpy of evaporation of the working medium;
wherein the condensate transport includes a surface comprising adhesive and/or varnish with fibers directed thereon.

2. The device as claimed in claim 1, wherein the electronic components are arranged on a printed circuit board in the electronics housing.

3. The device as claimed in claim 2, wherein the printed circuit board comprises part of the electronics housing.

4. The device as claimed in claim 1, wherein a wall of the electronics housing comprises a metal.

5. The device as claimed in claim 1, wherein a wall of the electronics housing comprises fiber composite material and/or composite material.

6. The device as claimed in claim 1, wherein the working medium comprises a coolant having a boiling point within range of 10° C. to 200° C.

7. The device as claimed in claim 1, wherein the working medium comprises a nonflammable or low-flammability coolant having a GWP value of less than 170.

8. The device as claimed in claim 1, wherein the working medium comprises a fluid having a boiling point at standard pressure of 10° C. to 200° C.

9. The device as claimed in claim 1, further comprising a flocked carpet with or without structuring over at least part an inside of the housing.

10. The device as claimed in claim 1, further comprising a coating of adhesive and/or varnish over at least part of an inside of the housing.

11. The device as claimed in claim 1, wherein the flocked carpet includes patterns and/or free areas.

12. The device as claimed in claim 1, wherein the electronic components coating of protective varnish acting as an adhesive for the flocking.

13. The device as claimed in claim 1, wherein the condensate transport comprises open pores in ceramics, foams, and/or composite materials.

14. The device as claimed in claim 1, wherein the condensate transport comprises channels.

15. The device as claimed in claim 1, wherein the printed circuit board comprises part of the electronics housing.
